(19) United States
(12) Patent Application Publication
(10) Pub. No.: US 2017/0170185 A1
(43) Pub. Date: Jun. 15, 2017

(54) METHOD OF FABRICATING A SEMICONDUCTOR DEVICE

(71) Applicant: SAMSUNG ELECTRONICS CO., LTD., Suwon-si (KR)

(72) Inventors: Kyung-Eun KIM, Seoul (KR); Yong Kwan KIM, Yongin-si (KR); Sehyoung AHN, Seoul (KR); Semyeong JANG, Gunpo-si (KR); Jaehyoung CHOI, Hwaseong-si (KR); Bong-Soo KIM, Yongin-si (KR); Yoosang HWANG, Suwon-si (KR)

(21) Appl. No.: 15/262,025

(22) Filed: Sep. 12, 2016

(30) Foreign Application Priority Data
Dec. 10, 2015 (KR) 10-2015-0176056

(51) Int. Cl. H01L 27/108; H01L 21/283; H01L 21/3115; H01L 49/02

(52) U.S. Cl. CPC H01L 27/1085; H01L 28/60; H01L 21/283; H01L 21/31155

(57) ABSTRACT

A method of fabricating a semiconductor device includes forming a mold structure including a lower support layer and an upper support layer sequentially stacked on a substrate, doping portions of the upper and lower support layers with impurities to divide each of the upper and lower support layers into first portions doped with the impurities and a second portion surrounding the first portions in a plan view, and removing the first portions of the upper and lower support layers to form an upper support pattern having first openings and a lower support pattern having second openings.

### CROSS-REFERENCE TO RELATED APPLICATION

Korean Patent Application No. 10-2015-0176056, filed on Dec. 10, 2015, in the Korean Intellectual Property Office, and entitled: “Method of Fabricating A Semiconductor Device,” is incorporated by reference herein in its entirety.

### BACKGROUND

1. Field

Embodiments relate to a method of fabricating a semiconductor device.

2. Description of the Related Art

Light, small, high-speed, multi-functional, high-performance, high-reliable, and low-priced electronic components have been increasingly demanded in products of the electronic industry (e.g., portable phones and note books).

To satisfy these demands, it is desirable to increase the integration density of semiconductor memory devices. In addition, it is desirable to improve performance of semiconductor memory devices.

A capacitance of a capacitor may be increased to improve reliability of a highly integrated semiconductor memory device including the capacitor. For example, the capacitance of the capacitor may increase as an aspect ratio of a lower electrode of the capacitor increases. Thus, research has been conducted regarding a process techniques for forming a capacitor having a high aspect ratio.

### SUMMARY

Embodiments are directed to a method of fabricating a semiconductor device, including forming a mold structure including a lower support layer and an upper support layer that are sequentially stacked on a substrate, doping portions of the upper and lower support layers with impurities to divide each of the upper and lower support layers into first portions doped with the impurities and a second portion surrounding the first portions in a plan view, and removing the first portions of the upper and lower support layers to form an upper support pattern having first openings and a lower support pattern having second openings.

Embodiments are also directed to a method of fabricating a semiconductor device including forming a mold structure including a mold layer and a preliminary support layer that are sequentially stacked on a substrate, forming lower electrodes penetrating the mold structure, doping portions of the preliminary support layer with impurities to form a support layer including first portions doped with the impurities, the first portions being in contact with portions of the lower electrodes, removing the first portions of the support layer to form a support pattern having openings exposing portions of the lower electrodes and the mold layer, and removing the mold layer exposed through the openings to expose sidewalls of the lower electrodes.

Embodiments are also directed to a method of fabricating a semiconductor device including forming a mold structure including at least a first mold layer, a lower support layer, a second mold layer and an upper support layer that are sequentially stacked on a substrate, forming lower electrodes to extend through the upper support layer, second mold layer, lower support layer and first mold layer, each lower electrode contacting a contact plug in the substrate, forming a mask pattern on the mold structure to define regions in the mold structure for forming upper electrodes, doping the upper support layer and the lower support layer in the regions for forming upper electrodes with impurities such that each of the upper and lower support layers are divided into first portions doped with the impurities, the first portions being in the regions for forming the upper electrodes, and a second portion surrounding the first portions in a plan view, such that the first portions of the upper and lower support layers have an etching selectivity with respect to the second portions, and removing the first portion of the upper support layer, the second mold layer, the first portion of the lower support layer and the first mold layer in the region for forming upper electrodes, wherein portions of the lower electrodes adjoining the region for forming upper electrodes are exposed, and wherein at least one of the first portion of the upper support layer, the second mold layer, the first portion of the lower support layer and the first mold layer in the region for forming upper electrodes is removed by wet etching using an etchant having an etch selectivity that preferentially removes the first portions relative to the second portions.

### BRIEF DESCRIPTION OF THE DRAWINGS

Features will become apparent to those of skill in the art by describing in detail exemplary embodiments with reference to the attached drawings in which:

FIGS. 1A to 7A illustrate plan views depicting stages of a method of fabricating a semiconductor device, according to some embodiments.

FIGS. 1B to 7B illustrate cross-sectional views taken along lines I-I′ of FIGS. 1A to 7A, respectively, to depict stages of a method of fabricating a semiconductor device, according to some embodiments.

FIGS. 8A to 12A illustrate plan views depicting stages of a method of fabricating a semiconductor device, according to some embodiments.

FIGS. 8B to 12B illustrate cross-sectional views taken along lines II-II′ of FIGS. 8A to 12A, respectively, to depict stages of a method of fabricating a semiconductor device, according to some embodiments.

FIGS. 13A to 17A illustrate plan views depicting stages of a method of fabricating a semiconductor device, according to some embodiments.

FIGS. 13B to 17B illustrate cross-sectional views taken along lines III-III′ of FIGS. 13A to 17A, respectively, to depict stages of a method of fabricating a semiconductor device, according to some embodiments.

FIG. 18A illustrates a plan view depicting a stage in method of fabricating a semiconductor device, according to some embodiments.

FIGS. 18B and 18C illustrate cross-sectional views taken along a line IV-IV′ of FIG. 18A to depict stages of a method of fabricating a semiconductor device, according to some embodiments.

FIGS. 19 to 22 illustrate cross-sectional views depicting a stages of method of fabricating a semiconductor device.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration.

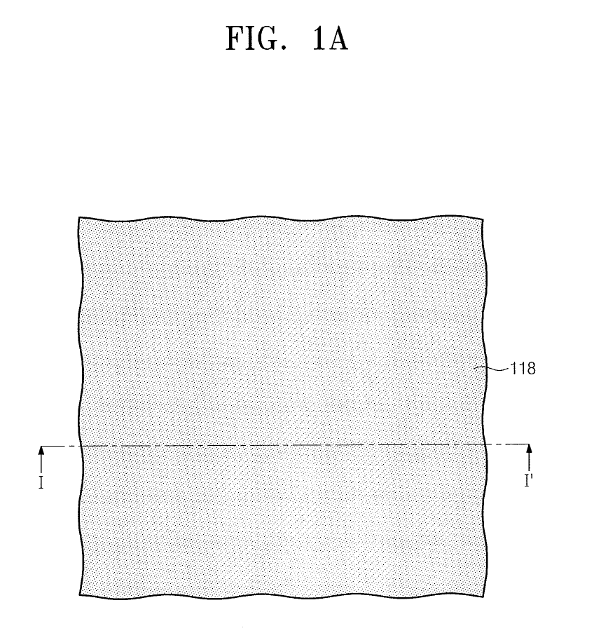

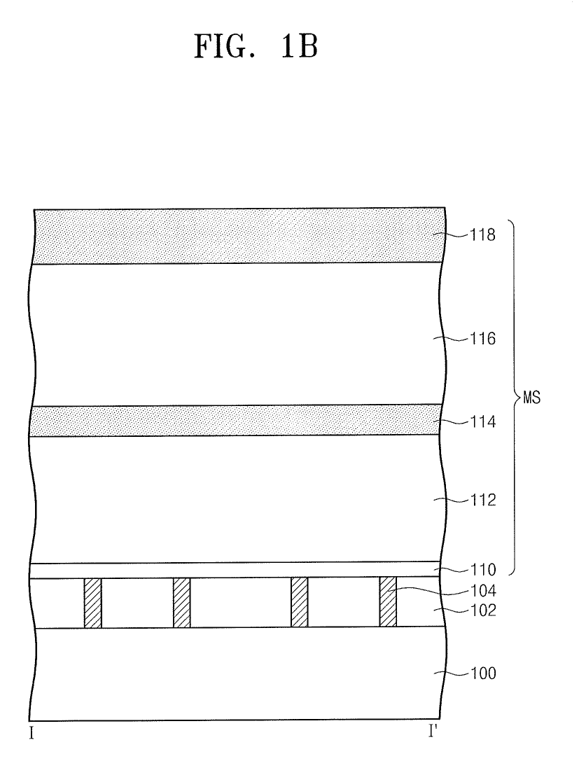

FIGS. 1A to 7A illustrate plan views depicting stages of a method of fabricating a semiconductor device, according to some embodiments. FIGS. 1B to 7B illustrate cross-sectional views taken along lines I-I′ of respective ones of FIGS. 1A to 7A to illustrate stages of a method of fabricating a semiconductor device, according to some embodiments.

Referring to FIGS. 1A and 1B, an interlayer insulating layer 102 may be formed on a substrate 100. The substrate 100 may be a semiconductor substrate such as a silicon substrate, a germanium substrate, or a silicon-germanium (SiGe) substrate. For example, the interlayer insulating layer 102 may include at least one of a silicon oxide layer, a silicon nitride layer, or a silicon oxynitride layer.

Contact plugs 104 may be formed to penetrate the interlayer insulating layer 102. The contact plugs 104 may include at least one of a doped semiconductor material (e.g., doped poly-crystalline silicon), a metal-semiconductor compound (e.g., tungsten silicide), a conductive metal nitride (e.g., titanium nitride, tantalum nitride, or tungsten nitride), or a metal (e.g., titanium, tungsten, or tantalum).

Word lines, and bit lines intersecting the word lines, may be formed on and/or in the substrate 100. The interlayer insulating layer 102 may be formed to cover the word lines and the bit lines. Dopant regions may be formed in the substrate 100 at both sides of each of the word lines, and each of the contact plugs 104 may be connected to one of the dopant regions.

A mold structure MS may be formed on the interlayer insulating layer 102. The mold structure MS may include an etch stop layer 110, a first mold layer 112, a first support layer 114, a second mold layer 116, and a second support layer 118, which are sequentially stacked on the interlayer insulating layer 102.

The etch stop layer 110 may be formed of a material having an etch selectivity with respect to the interlayer insulating layer 102 and the first mold layer 112. For example, the etch stop layer 110 may be or may include a silicon nitride (SiN) layer or a silicon oxynitride (SiON) layer. Each of the first and second mold layers 112 and 116 may be or may include a silicon oxide (SiO₂) layer or an oxide layer including germanium (Ge).

The first and second support layers 114 and 118 may be formed of a material having an etch selectivity with respect to the first and second mold layers 112 and 116. For example, each of the first and second support layers 114 and 118 may be or may include a silicon nitride (SiN) layer or a silicon carbonitride (SiCN) layer. In some embodiments, the second support layer 118 may be thicker than the first support layer 114. In some embodiments, a distance between the first support layer 114 and the second support layer 118 may be about 400 nm or more. Two support layers are illustrated as an example in FIG. 1B. In some implementations, the number of the support layers may be one, three or more.

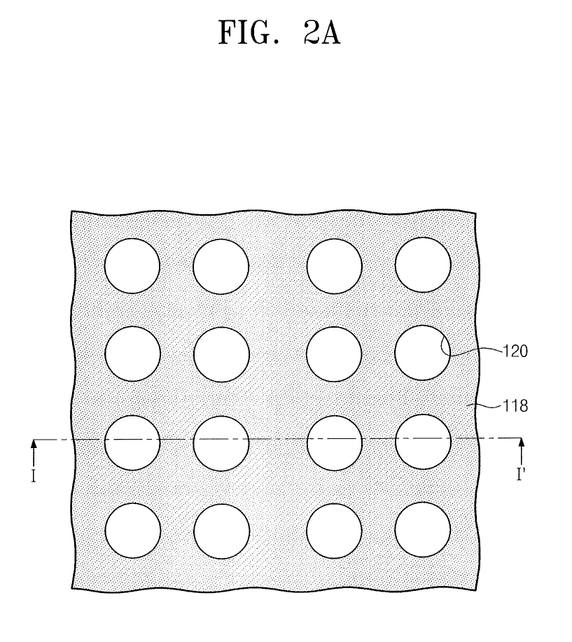

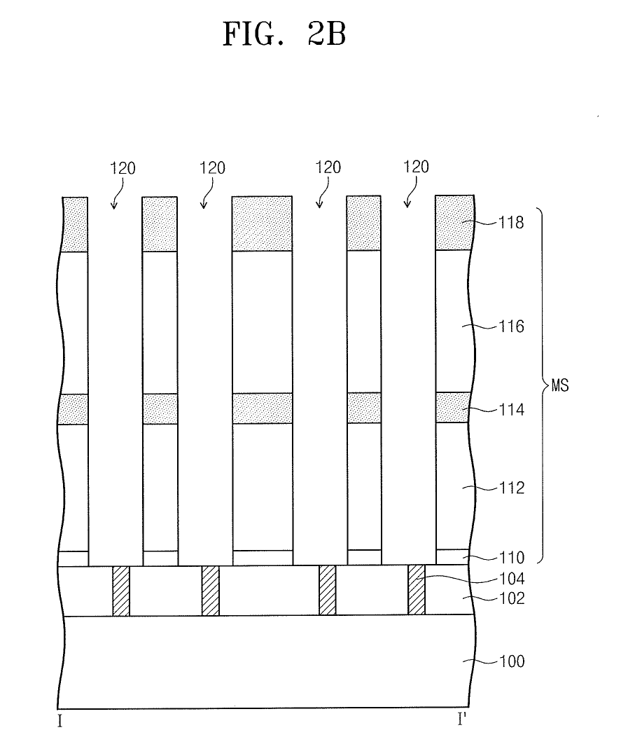

Referring to FIGS. 2A and 2B, the mold structure MS may be patterned using an anisotropic etching process to form electrode holes 120 penetrating the mold structure MS. In some embodiments, a mask pattern defining the electrode holes 120 may be formed on the mold structure MS. The second support layer 118, the second mold layer 116, the first support layer 114, and the first mold layer 112 may be sequentially etched using the mask pattern as an etch mask to expose the etch stop layer 110, and then the etch stop layer 110 may be etched to expose top surfaces of the contact plugs 104.

A difference between an etch rate of the mold layers 112 and 116 and an etch rate of the support layers 114 and 118 may be 10% or less in the anisotropic etching process for the formation of the electrode holes 120. In some embodiments, the anisotropic etching process for the formation of the electrode holes 120 may use an etching gas to etch the first and second mold layers 112 and 116 and an etching gas to etch the first and second support layers 114 and 118.

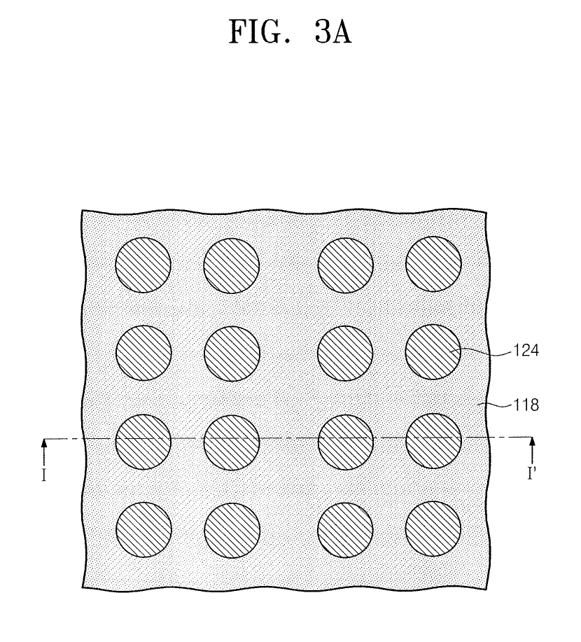

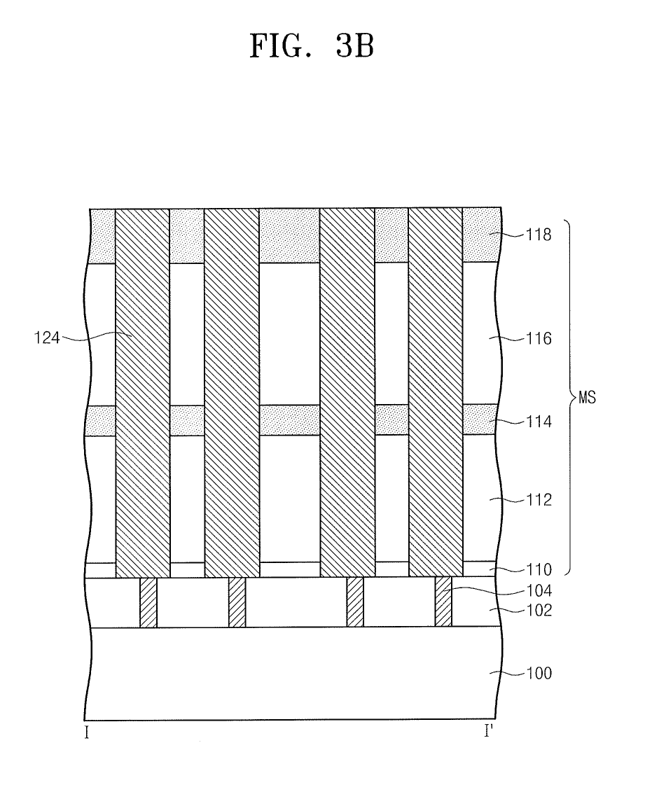

Referring to FIGS. 3A and 3B, lower electrodes 124 may be formed in the electrode holes 120, respectively. For example, a conductive layer may be formed on the mold structure MS to fill the electrode holes 120, and a planarization process may be performed on the conductive layer until a top surface of the second support layer 118 is exposed, thereby forming the lower electrodes 124. The lower electrodes 124 may be spaced apart from each other and may each be electrically connected to a respective one of the contact plugs 104.

To fill the electrode holes 120 having a high aspect ratio with the conductive layer, the conductive layer may be deposited by a layer-formation technique having an excellent step coverage property, e.g., a chemical vapor deposition (CVD) technique or an atomic layer deposition (ALD) technique. The planarization process may be performed using a chemical mechanical polishing (CMP) process or an etch-back process. Each of the lower electrodes 124 may have a cylindrical shape, a pillar shape, or a hybrid cylindrical shape (a combination of a pillar shape and a cylindrical shape).

The lower electrodes 124 may include at least one of a metal material (e.g., cobalt, titanium, nickel, tungsten, or molybdenum), a metal nitride (e.g., titanium nitride (TiN), titanium-silicon nitride (TiSiN), titanium-aluminum nitride (TiAlN), tantalum nitride (TaN), tantalum-aluminum nitride (TaAlN), or tungsten nitride (WN)), a noble metal (e.g., platinum (Pt), ruthenium (Ru), or iridium (Ir)), a conductive oxide (e.g., PtO, RuO₂, IrO₂, SrRuO₃ (SRO), (Ba,Sr)RuO₃ (BSRO), CaRuO₃ (CRO), or LSCo), or a metal silicide.

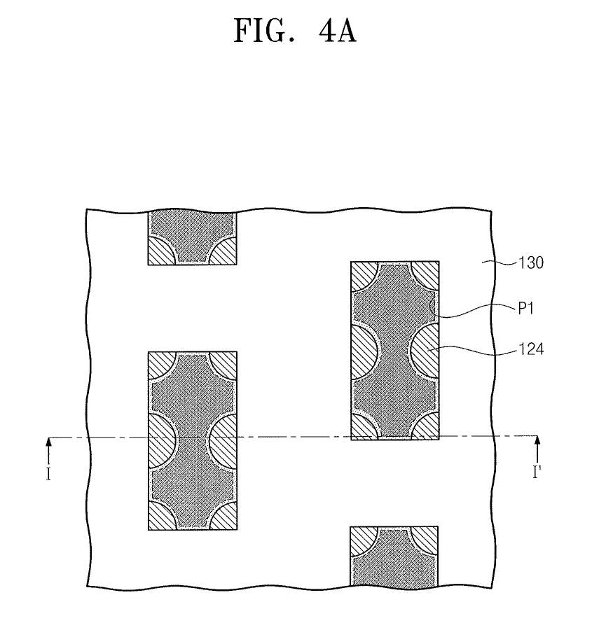

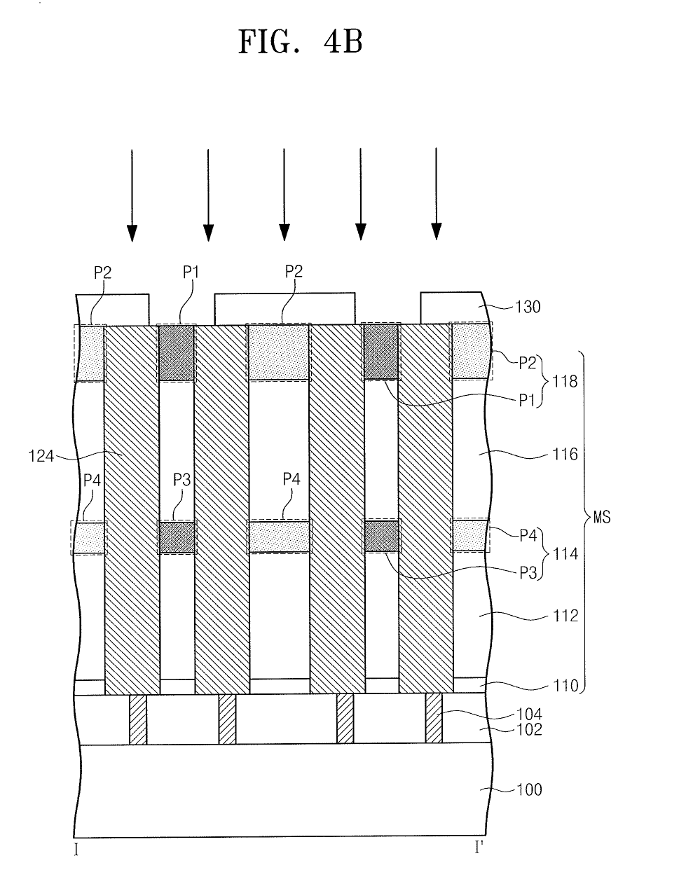

Referring to FIGS. 4A and 4B, a mask pattern 130 may be formed on the mold structure MS. The mask pattern 130 may expose first portions P1 of the second support layer 118. Third portions P3 of the first support layer 114 may vertically overlap with the first portions P1 of the second support layer 118. For example, the mask pattern 130 may have openings that expose and define the first portions P1 of the second support layer 118. The openings may vertically overlap with and define the first portions P1 of the second support layer 118 and the third portions P3 of the first support layer 114. A second portion P2 of the second support layer 118 may be defined as corresponding to the rest of the second support layer 118 except the first portions P1. The second portion P2 of the second support layer 118 may surround the first portions P1 of the second support layer 118 when viewed from a plan view. A fourth portion P4 of the first support layer 114 may be defined as corresponding to the rest of the first support layer 114 except the third portions P3. The fourth portion P4 of the first support layer 114 may surround the third portions P3 of the first support layer 114 when viewed from a plan view.

The mask pattern 130 may include one or more layers. In some embodiments, the mask pattern 130 may include at least one of a poly-silicon layer, an oxide layer, a spin-on-hardmask (SOH) layer, or an amorphous carbon layer (ACL).

Impurities may be provided into the first portions P1 of the second support layer 118 exposed by the mask pattern 130 and the third portions P3 of the first support layer 114 disposed below the first portions P1. For example, the first portions P1 of the second support layer 118 and the third portions P3 of the first support layer 114 may be doped with impurities. By doping the first portions P1 and the third portions P3 with impurities, the first portions P1 of the second support layer 118 may be converted into a material having an etch selectivity with respect to the second portion P2 of the second support layer 118, and the third portions P3 of the first support layer 114 may be converted into a material having an etch selectivity with respect to the fourth portion P4 of the first support layer 114.

The impurities may be provided by an ion implantation process. The ion implantation process may be performed using impurities including boron (B), carbon (C), germanium (Ge), and/or fluorine (F). For example, after the doping process, the first portions P1 of the second support layer 118 and the third portions P3 of the first support layer 114 may include at least one of SiBN, SiCN, SiGeN, or SiFN.

The mask pattern 130 may be removed after the ion implantation process is performed.

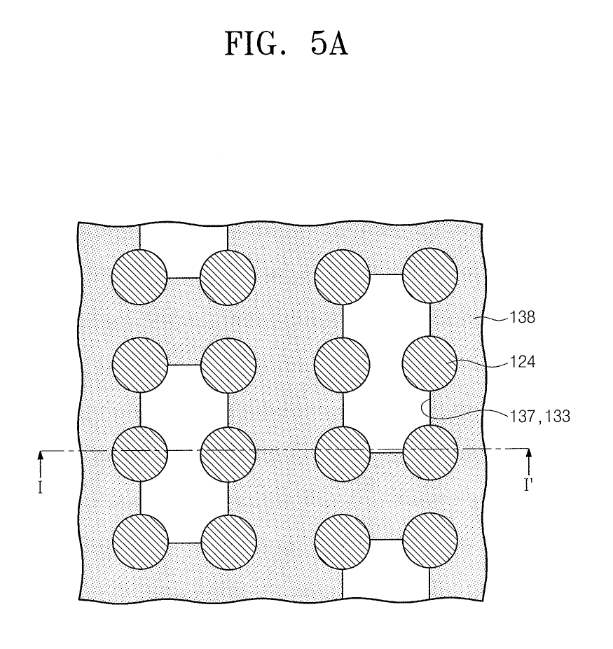

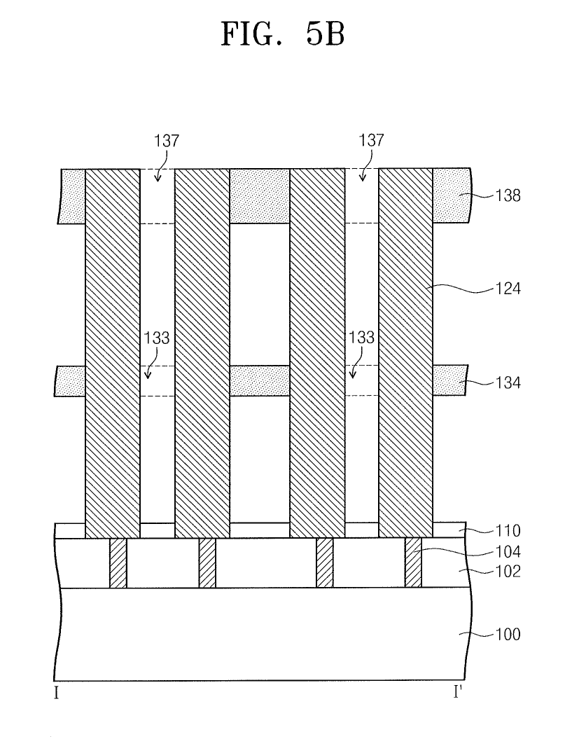

Referring to FIGS. 5A and 5B, a wet etching process may be performed to sequentially remove the first portions P1 of the second support layer 118, the second mold layer 116, the third portions P3 of the first support layer 114, and the first mold layer 112.

In some embodiments, the first portions P1 of the second support layer 118 may be etched using a first etching solution. At this time, the second portion P2 of the second support layer 118 may not be removed by the first etching solution. In other words, the first portions P1 of the second support layer 118 may be selectively removed from the second portion P2 of the second support layer 118. The first etching solution may include HF/NH₄F/H₂O (a LAL solution) or H₂SO₄/H₂O₂/H₂O (a SPA solution), as examples.

When the first portions P1 of the second support layer 118 are removed, a second support pattern 138 having first openings 137 may be formed. Portions of sidewalls of upper portions of the lower electrodes 124 may be exposed by the first openings 137, and the second support pattern 138 may cover other portions of the sidewalls of the upper portions of the lower electrodes 124.

Subsequently, a second etching solution may be provided through the first openings 137 of the second support pattern 138 to remove the second mold layer 116. The second mold layer 116 may be removed to expose sidewalls of the lower electrodes 124 disposed between the second support pattern 138 and the first support layer 114, a bottom surface of the second support pattern 138, and a top surface of the first support layer 114. The second etching solution may include a LAL solution, as an example.

Subsequently, the third portions P3 of the first support layer 114 may be removed using a third etching solution. Removing the third portions P3 of the first support layer 114 using the third etching solution may be performed such that the fourth portion P4 is not removed. For example, the third portions P3 of the first support layer 114 may be selectively removed from the fourth portion P4 of the first support layer 114. The third etching solution may include la LAL solution or a SPA solution, as an example.

When the third portions P3 of the first support layer 114 are removed, a first support pattern 134 having second openings 133 may be formed. Portions of sidewalls of lower portions of the lower electrodes 124 may be exposed by the second openings 133, and the first support pattern 134 may cover other portions of the sidewalls of the lower portions of the lower electrodes 124.

Subsequently, a fourth etching solution may be provided through the second openings 133 of the first support pattern 134 to remove the first mold layer 112. The first mold layer 112 may be removed to expose a bottom surface of the first support pattern 134, a top surface of the etch stop layer 110, and the lower electrodes 124 disposed between the first support pattern 134 and the etch stop layer 110. At this time, the etch stop layer 110 may prevent the interlayer insulating layer 102 from being etched during the removal of the first mold layer 112. The fourth etching solution may include a LAL solution, as an example.

In some embodiments, the first portions P1 of the second support layer 118, the second mold layer 116, the third portions P3 of the first support layer 114, and the first mold layer 112 may be removed using the same etching solution. In this case, the first to fourth etching solutions may include a LAL solution. In some embodiments, the first portions P1 of the second support layer 118, the second mold layer 116, the third portions P3 of the first support layer 114, and the first mold layer 112 may be removed using different etching solutions. In this case, the first and third etching solutions etching the first and third portions P1 and P3 may include, for example, a SPA solution, and the second and fourth etching solutions etching the second and first mold layers 116 and 112 may include, for example, a LAL solution.

When a distance between adjacent lower electrodes 124 is small and a vertical distance between the first and second support layers 114 and 118 is great, it may be difficult to etch the third portions P3 of the first support layer 114 by a dry etching process using an etching gas provided through the first openings 137 of the second support pattern 138 disposed between the lower electrodes 124. In addition, if a dry etching process were to be performed for a long time to etch the third portions P3 of the first support layer 114, the sidewalls of the lower electrodes 124 disposed between the second and first support patterns 138 and 134 could be damaged by the dry etching process.

However, according to some embodiments, the third portions P3 of the first support layer 114 may be converted into the material having an etch selectivity with respect to the fourth portion P4 of the first support layer 114. The third portions P3 of the first support layer 114 may be removed by the wet etching process to form the first support pattern 134. As a result, the support pattern 134 may be formed with little or no defects and/or damage to the lower electrodes 124, thereby improving reliability of the semiconductor device.

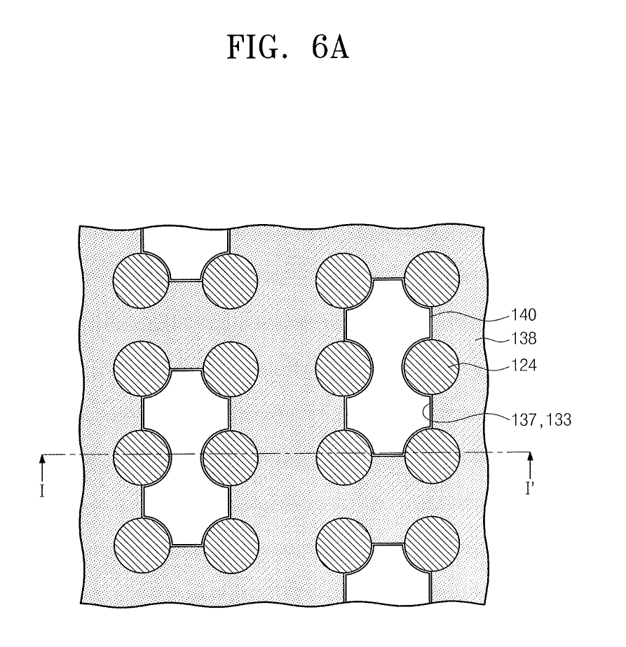

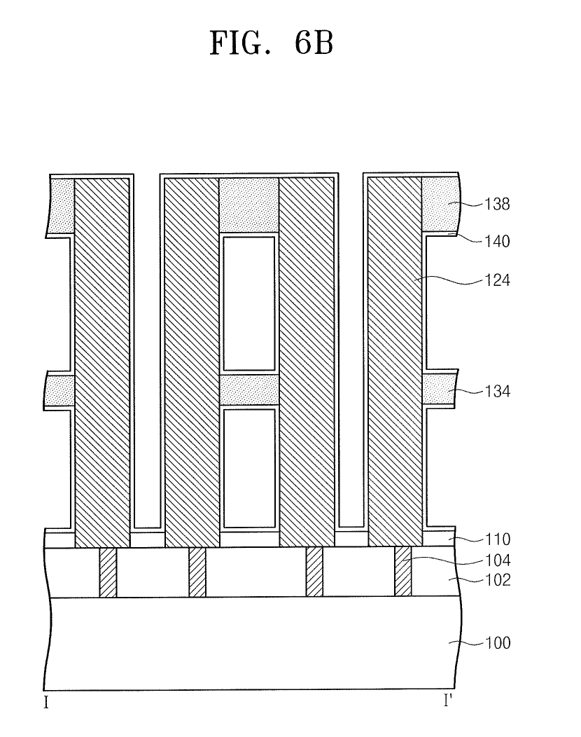

Referring to FIGS. 6A and 6B, a dielectric layer 140 may be formed on the lower electrodes 124 exposed by the first and second support patterns 134 and 138. The dielectric layer 140 may be formed of a dielectric material provided through the first and second openings 137 and 133. The dielectric layer 140 may conformally cover sidewalls and top surfaces of the lower electrodes 124, the top and bottom surfaces of the first support pattern 134, the top and bottom surfaces of the second support pattern 138, and the top surface of the etch stop layer 110.

The dielectric layer 140 may be formed by a layer-formation technique having an excellent step coverage property, e.g., a CVD technique or an ALD technique. For example, the dielectric layer 140 may be formed of a single layer or multi-layer including at least one of a metal oxide (e.g., HfO₂, ZrO₂, Al₂O₃, La₂O₃, Ta₂O₃, or TiO₂) or a perovskite dielectric material (e.g., SrTiO₃ (STO), (Ba,Sr)TiO₃ (BST), BaTiO₃, PZT, or PLZT).

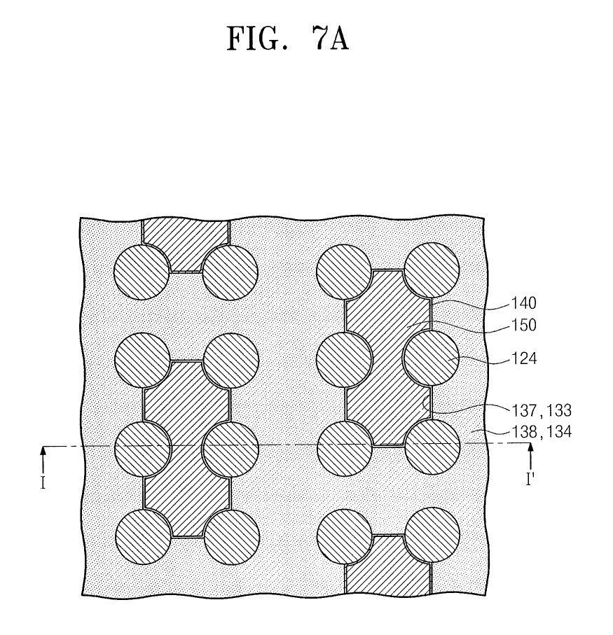

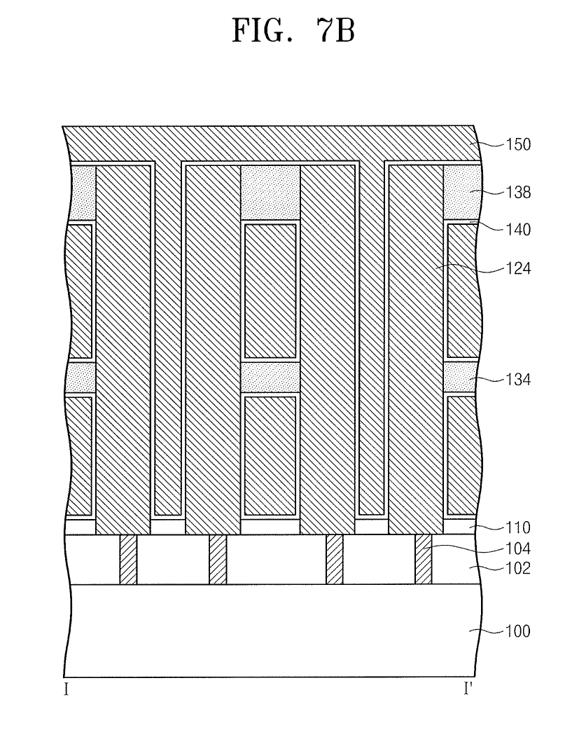

Referring to FIGS. 7A and 7B, an upper electrode layer 150 may be formed on the dielectric layer 140. The upper electrode layer 150 may fill the first and second openings 137 and 133, a space between the etch stop layer 110 and the first support pattern 134, and a space between the first support pattern 134 and the second support pattern 138. For example, the upper electrode layer 150 may cover the exposed portions of lower electrodes 124.

The upper electrode layer 150 may be formed of at least one of a semiconductor material doped with dopants, a metal material, a metal nitride, or a metal silicide. In some embodiments, the upper electrode layer 150 may be formed of a high melting point metal material such as cobalt, titanium, nickel, tungsten, and/or molybdenum. In some embodiments, the upper electrode layer 150 may be formed of a metal nitride such as titanium nitride (TiN), titanium-aluminum nitride (TiAlN), and/or tungsten nitride (WN). In some embodiments, the upper electrode layer 150 may be formed of at least one of platinum (Pt), ruthenium (Ru), or iridium (Ir).

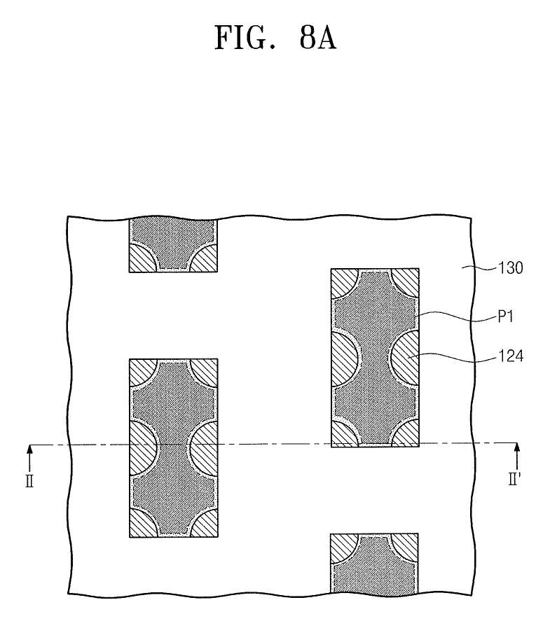

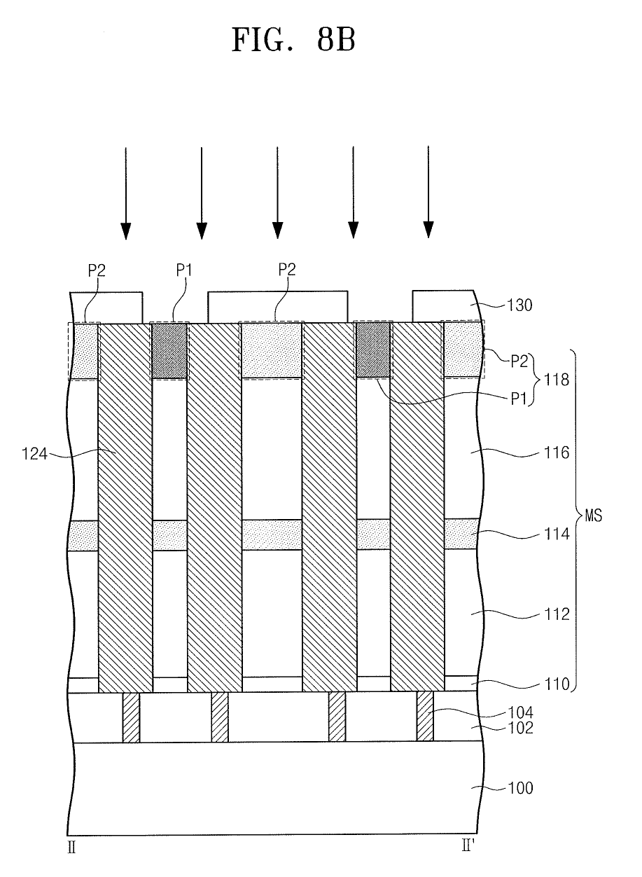

FIGS. 8A to 12A illustrate plan views depicting stages of a method of fabricating a semiconductor device, according to some embodiments. FIGS. 8B to 12B are cross-sectional views taken along lines II-II′ of respective ones of FIGS. 8A to 12A to illustrate the method of fabricating a semiconductor device. Hereinafter, the same elements as described in the above embodiments will be indicated by the same reference numerals or the same reference designators. In addition, the descriptions to the same elements as in the above embodiments will not be repeated or will be mentioned only briefly for the purpose of ease and convenience in explanation.

In the present embodiment, a process of forming a mold structure MS and a process of forming lower electrodes 124 may be the same as described with reference to FIGS. 1A to 3A and 1B to 3B, and thus the descriptions thereto will not be repeated.

Referring to FIGS. 8A and 8B, a mask pattern 130 may be formed on the mold structure MS. The mask pattern 130 may expose first portions P1 of the second support layer 118.

An ion implantation process may be performed to dope the first portions P1 of the second support layer 118 with impurities. Thus, the first portions P1 of the second support layer 118 may be converted into a material having an etch selectivity with respect to a second portion P2 of the second support layer 118.

The ion implantation process may be performed using impurities including boron (B), carbon (C), germanium (Ge), and/or fluorine (F). For example, after the ion implantation process, the first portions P1 of the second support layer 118 may include at least one of SiBN, SiCN, SiGeN, or SiFN.

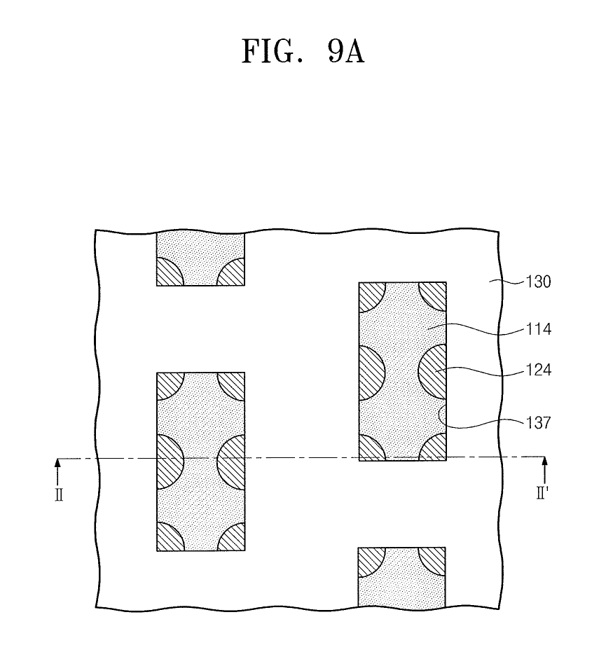

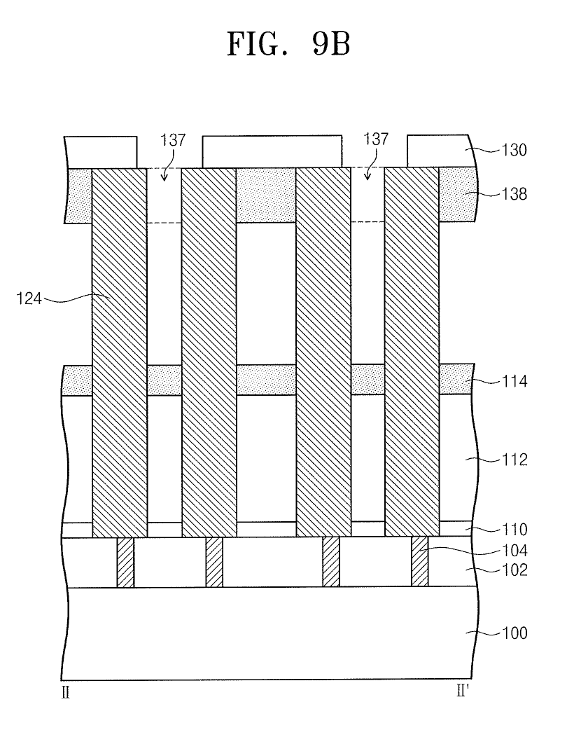

Referring to FIGS. 9A and 9B, the first portions P1 of the second support layer 118 may be removed to form a second support pattern 138 having first openings 137. The first portions P1 of the second support layer 118 may be removed by performing a wet etching process using a first etching solution. The second portion P2 of the second support layer 118 is not removed by the first etching solution. The first etching solution may include a LAL solution or a SPA solution, as examples.

Subsequently, the second mold layer 116 may be removed using a second etching solution provided through the first openings 137 of the second support pattern 138. The second mold layer 116 may be removed to expose sidewalls of the lower electrodes 124 disposed between the second support pattern 138 and the first support layer 114, a bottom surface of the second support pattern 138, and a top surface of the first support layer 114. The second support pattern 138 and the first support layer 114 may be formed of a material having an etch selectivity with respect to the second mold layer 116. Accordingly, the second support pattern 138 and the first support layer 114 may not be removed by the second etching solution when the second mold layer 116 is removed. The second etching solution may include a LAL solution, as an example.

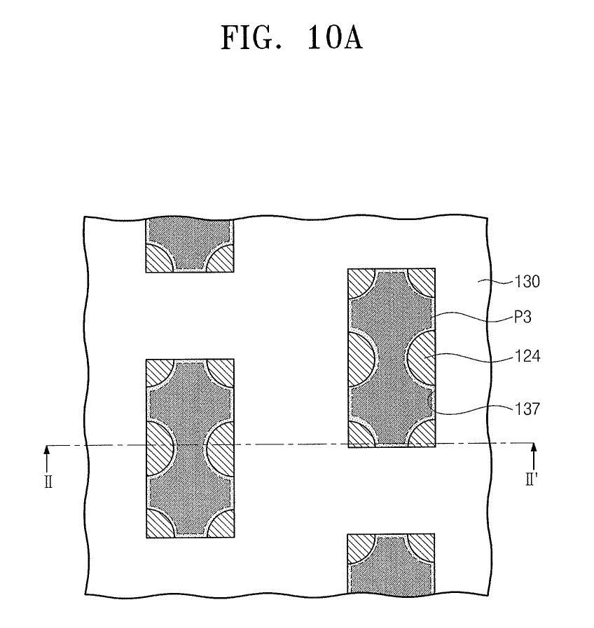

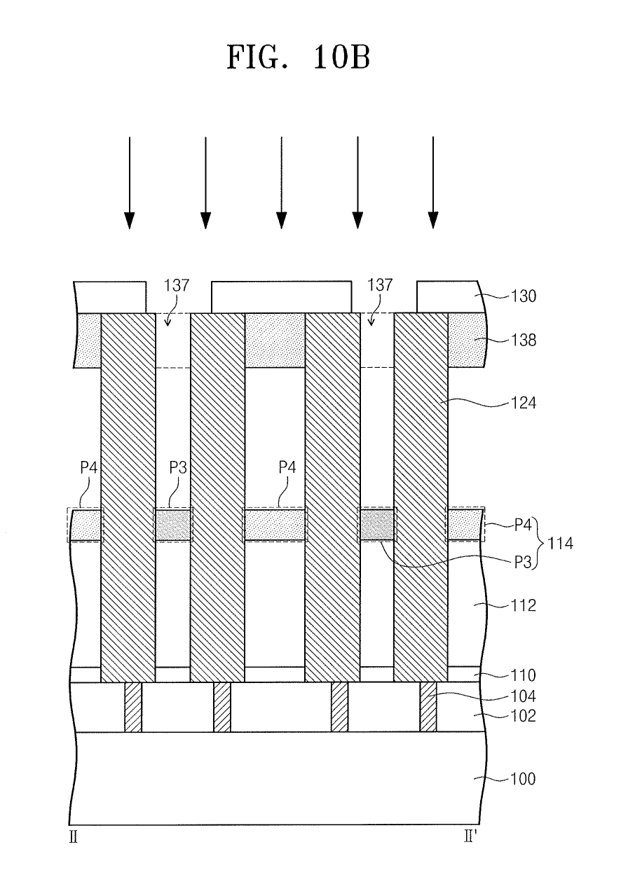

Referring to FIGS. 10A and 10B, impurities may be provided into third portions P3 of the first support layer 114 through the first openings 137 of the second support pattern 138 exposed by the mask pattern 130. Thus, the third portions P3 of the first support layer 114 may be converted into a material having an etch selectivity with respect to the second support pattern 138 and a fourth portion P4 of the first support layer 114. The impurities may be provided by an ion implantation process. The ion implantation process may be performed using impurities including boron (B), carbon (C), germanium (Ge), and/or fluorine (F). For example, after the ion implantation process, the third portions P3 of the first support layer 114 may include at least one of SiBN, SiCN, SiGeN, or SiFN.

Referring to FIGS. 11A and 11B, the third portions P3 of the first support layer 114 may be removed to form a first support pattern 134 having second openings 133. The third portions P3 of the first support layer 114 may be removed by performing a wet etching process using a third etching solution. The fourth portion P4 of the first support layer 114 may not be removed by the third etching solution. For example, the third etching solution may include a LAL solution or a SPA solution.

Subsequently, the first mold layer 112 may be removed using a fourth etching solution provided through the second openings 133 of the first support pattern 134. The first mold layer 112 may be removed to expose sidewalls of the lower electrodes 124 disposed between the first support pattern 134 and the etch stop layer 110, a bottom surface of the first support pattern 134, and a top surface of the etch stop layer 110. The first and second support patterns 134 and 138 may be formed of a material having an etch selectivity with respect to the first mold layer 114. Accordingly, the first and second support patterns 134 and 138 may not be removed by the fourth etching solution when the first mold layer 114 is removed. The fourth etching solution may include a LAL solution, as an example.

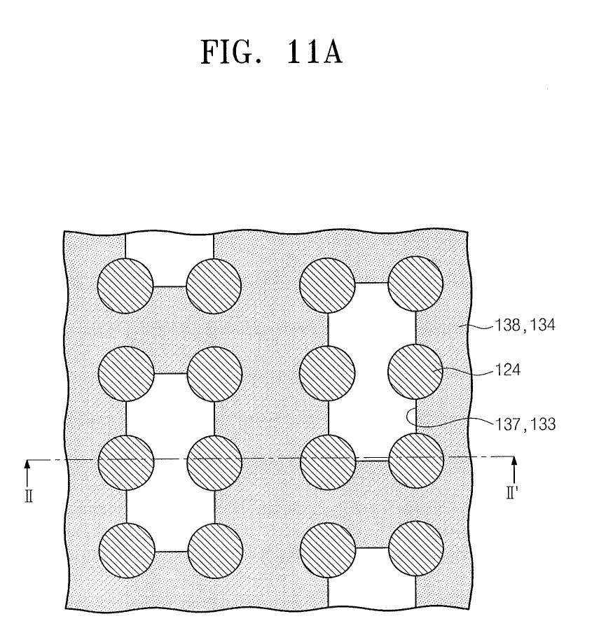

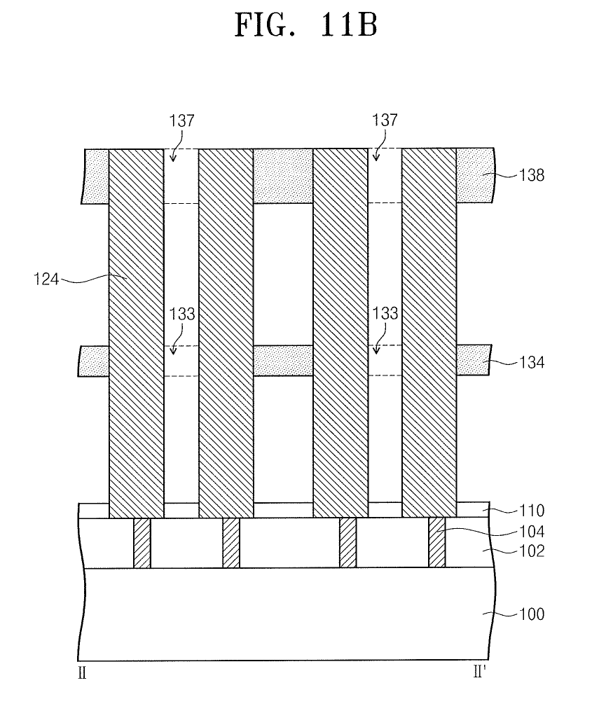

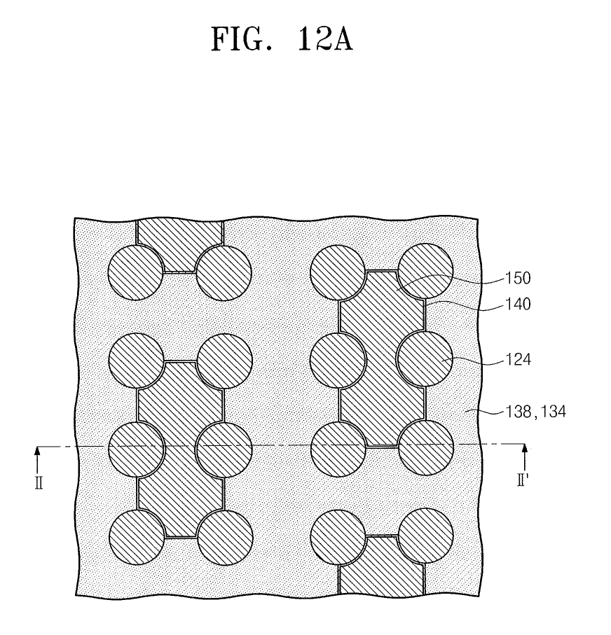

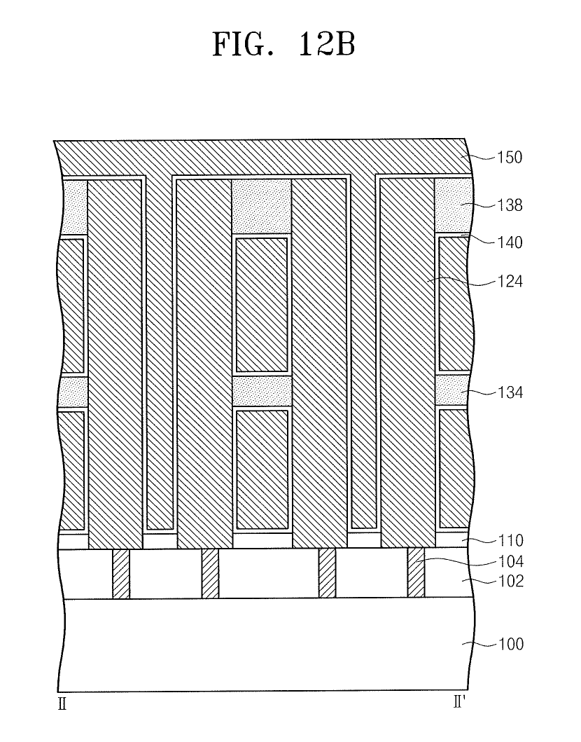

Referring to FIGS. 12A and 12B, a dielectric layer 140 and an upper electrode layer 150 may be sequentially formed on surfaces of the lower electrodes 124, the top and bottom surfaces of the first support pattern 134, the top and bottom surfaces of the second support pattern 138, and the top surface of the etch stop layer 110.

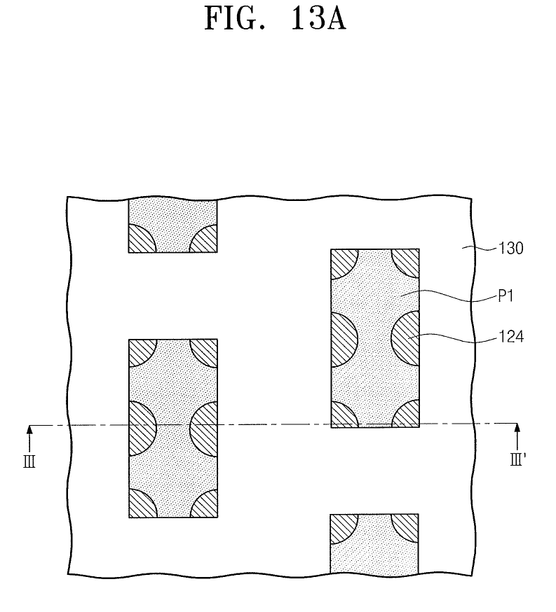

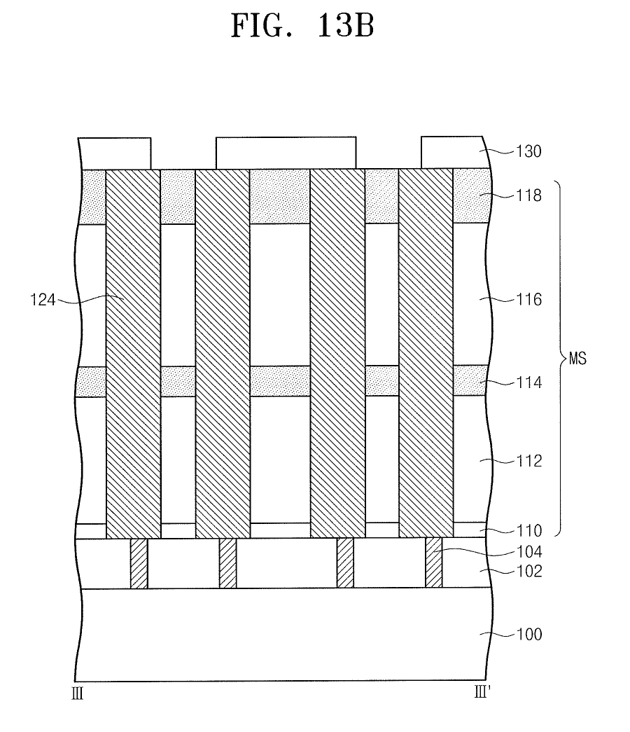

FIGS. 13A to 17A are plan views illustrating a method of fabricating a semiconductor device, according to some embodiments. FIGS. 13B to 17B are cross-sectional views taken along lines III-III′ of FIGS. 13A to 17A, respectively, to illustrate a method of fabricating a semiconductor device, according to some embodiments. In the present embodiment, a process of forming a mold structure MS and a process of forming lower electrodes 124 may be the same as described with reference to FIGS. 1A to 3A and 1B to 3B, and thus, the descriptions thereto will not be repeated.

Referring to FIGS. 13A and 13B, a mask pattern 130 may be formed on the mold structure MS. Portions of the second support layer 118 may be exposed by the mask pattern 130.

Referring to FIGS. 14A and 14B, the exposed portions of the second support layer 118 may be removed by a dry etching process, thereby forming a second support pattern 138 having first openings 137. Portions of the top surface of the second mold layer 116 may be exposed through the first openings 137 of the second support pattern 138. The dry etching process may be performed using an etching gas (e.g., a CₓF_{y}-based gas) having an etch selectivity with respect to the second mold layer 116. The etching gas of the dry etching process may selectively etch the exposed portions of the second support layer 118.

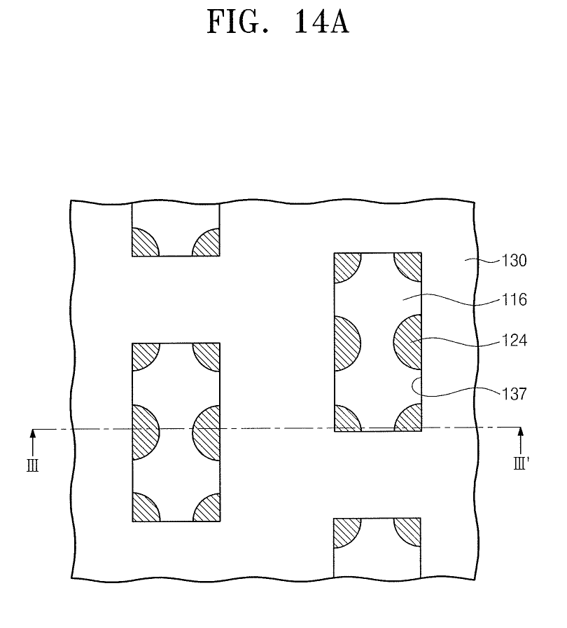

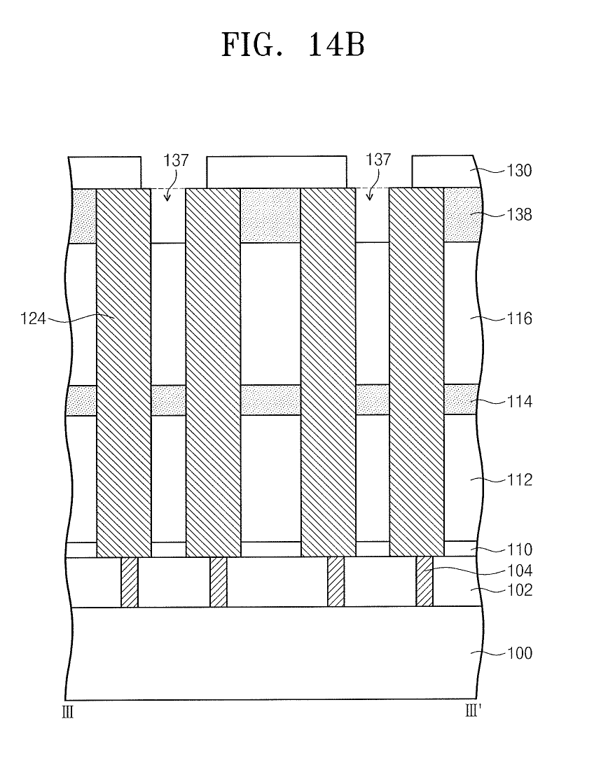

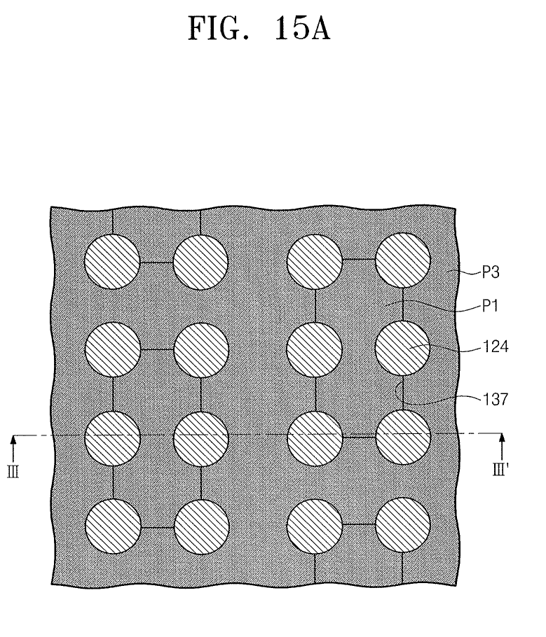

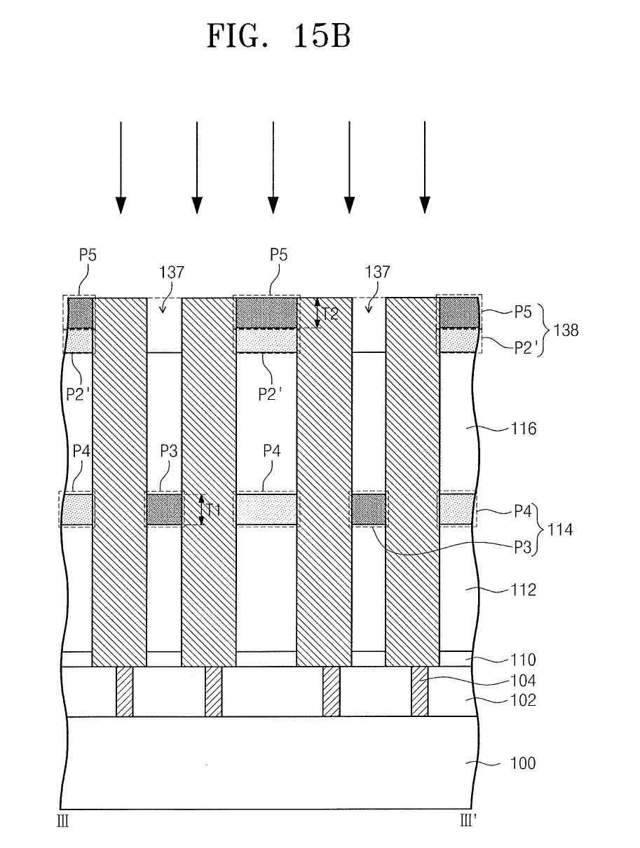

Referring to FIGS. 15A and 15B, the mask pattern 130 may be removed. Thus, a top surface of the second support pattern 138 may be exposed.

An ion implantation process may be performed on the substrate 100 having the first mold layer 112, the first support layer 114, the second mold layer 116, and the second support pattern 138 which are sequentially stacked. An upper portion P5 of the second support pattern 138 and first portions P3 of the first support layer 114 disposed under the first openings 137 may be doped with impurities by the ion implantation process. A second portion P4 of the first support layer 114 may correspond to the rest of the first support layer 114 except the first portions P3. The second portion P4 of the first support layer 114 may surround the first portions P3 of the first support layer 114 when viewed from a plan view. By the ion implantation process, the first portions P3 of the first support layer 114 and the upper portion P5 of the second support pattern 138 may be converted into a material having an etch selectivity with respect to the second portion P4 of the first support layer 114 and a lower portion P2′ of the second support pattern 138. A thickness T2 of the upper portion P5 of the second support pattern 138 may be substantially equal to a thickness T1 of the first portions P3 of the first support layer 114.

The ion implantation process may be performed using the impurities including boron (B), carbon (C), germanium (Ge), and/or fluorine (F). For example, after the ion implantation process, the first portions P3 of the first support layer 114 and the upper portion P5 of the second support pattern 138 may include at least one of SiBN, SiCN, SiGeN, or SiFN.

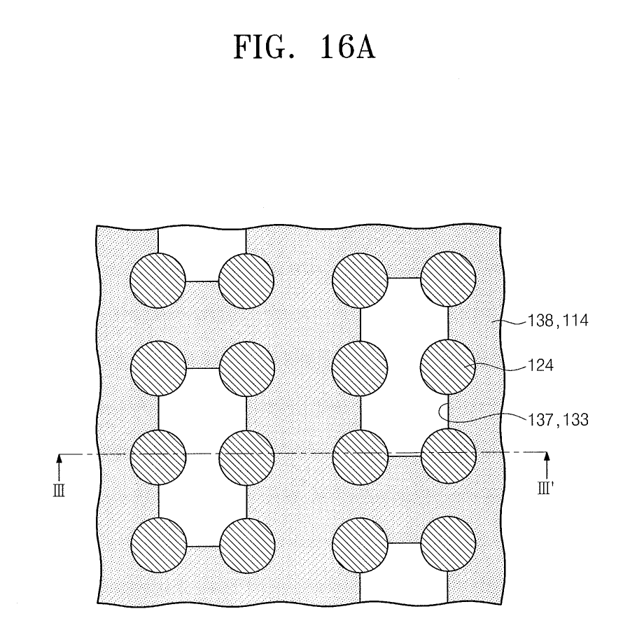

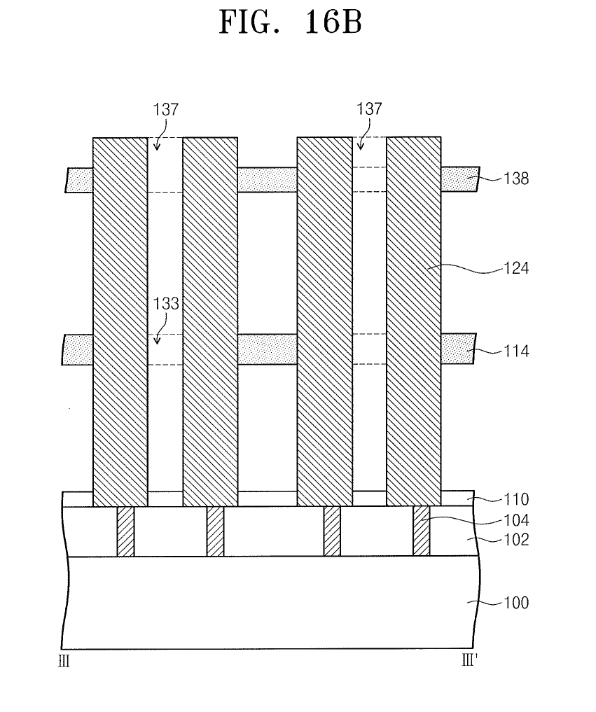

Referring to FIGS. 16A and 16B, a wet etching process may be performed to sequentially remove the upper portion P5 of the second support pattern 138, the second mold layer 116, the first portions P3 of the first support layer 114, and the first mold layer 112.

For example, the upper portion P5 of the second support pattern 138 may be removed using a first etching solution. The lower portion P2′ of the second support pattern 138 may not be removed by the first etching solution. For example, the upper portion P5 of the second support pattern 138 may be selectively removed from the lower portion P2′ of the second support pattern 138. When the upper portion P5 of the second support pattern 138 is removed, a thickness of the second support pattern 138 may be reduced. The first etching solution may include a LAL solution or a SPA solution, as examples.

The second mold layer 116 may be removed by a second etching solution provided through the first openings 137 of the second support pattern 138. The second mold layer 116 may be removed to expose a bottom surface of the second support pattern 138, sidewalls of the lower electrodes 124 disposed between the second support pattern 138 and the first support layer 114, and a top surface of the first support layer 114. For example, the second etching solution may include a LAL solution.

Subsequently, the first portions P3 of the first support layer 114 may be removed using a third etching solution. At this time, the second portion P4 of the first support layer 114 may not be removed by the third etching solution. Since the first portions P3 of the first support layer 114 are removed, a first support pattern 134 having second openings 133 may be formed. For example, the third etching solution may include a LAL solution or a SPA solution.

Subsequently, a fourth etching solution may be provided through the second openings 133 of the first support pattern 134 to remove the first mold layer 112. The first mold layer 112 may be removed to expose a bottom surface of the first support pattern 134, a top surface of the etch stop layer 110, and sidewalls of the lower electrodes 124 disposed between the first support pattern 134 and the etch stop layer 110. For example, the fourth etching solution may include a LAL solution.

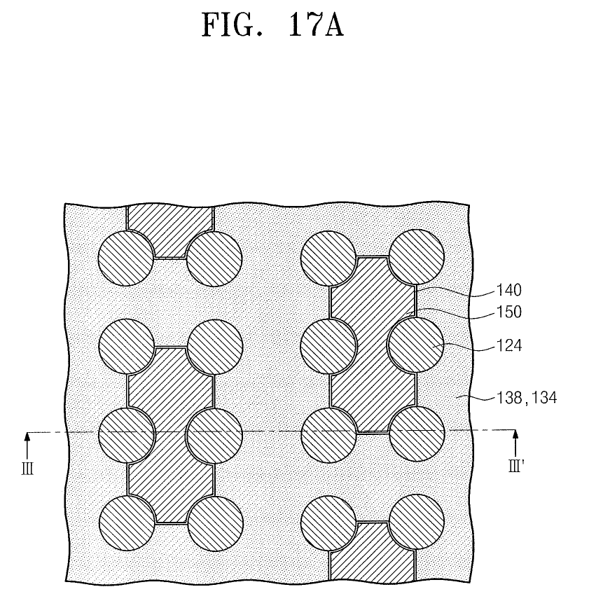

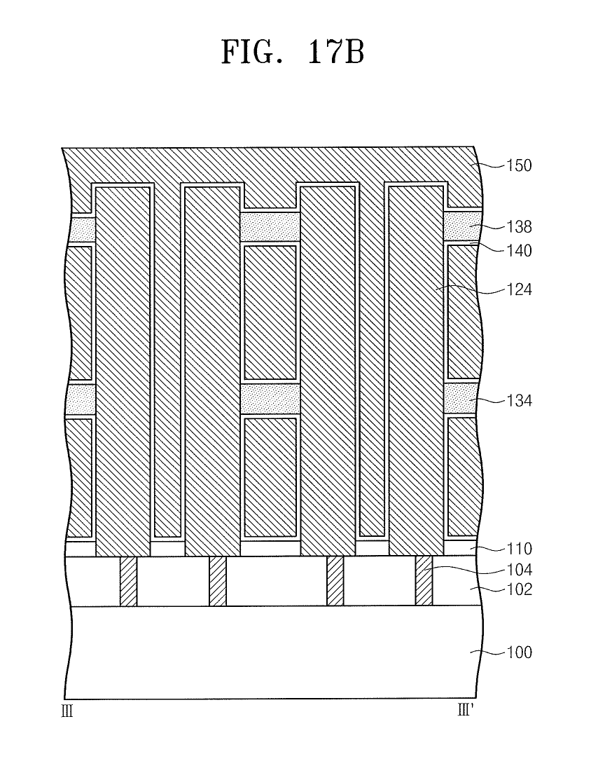

Referring to FIGS. 17A and 17B, a dielectric layer 140 and an upper electrode layer 150 may be sequentially formed on surfaces of the lower electrodes 124, the top and bottom surfaces of the first support pattern 134, the top and bottom surfaces of the second support pattern 138, and the top surface of the etch stop layer 110.

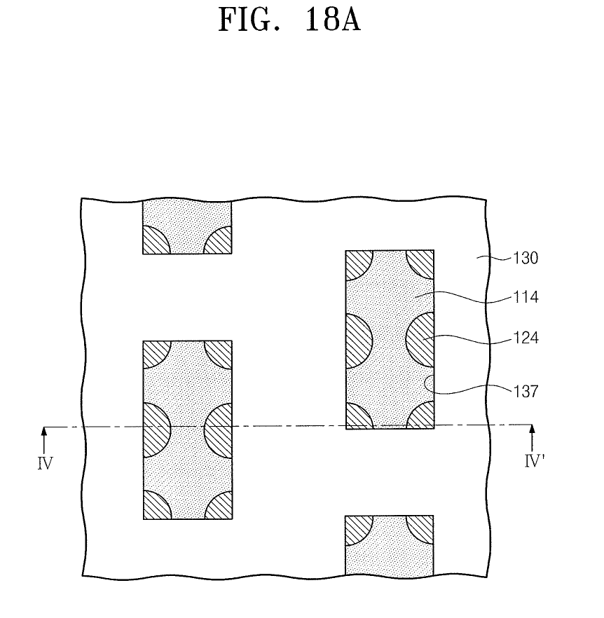

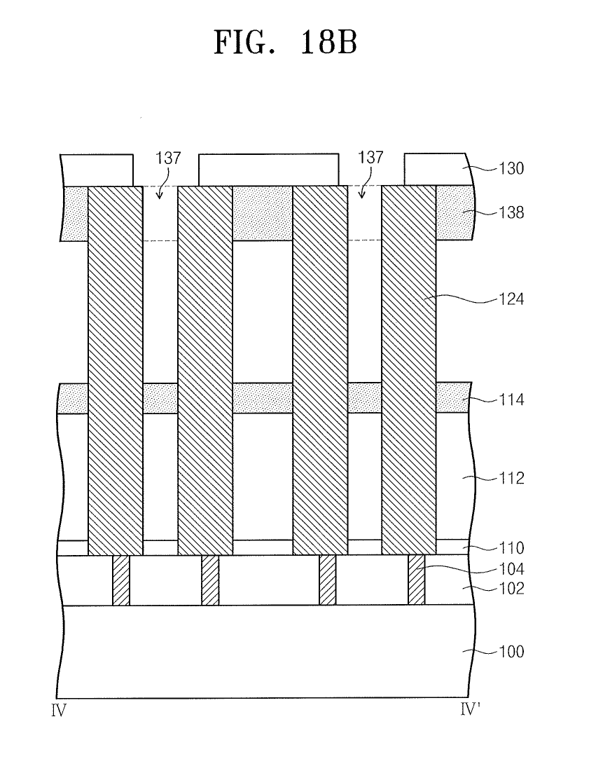

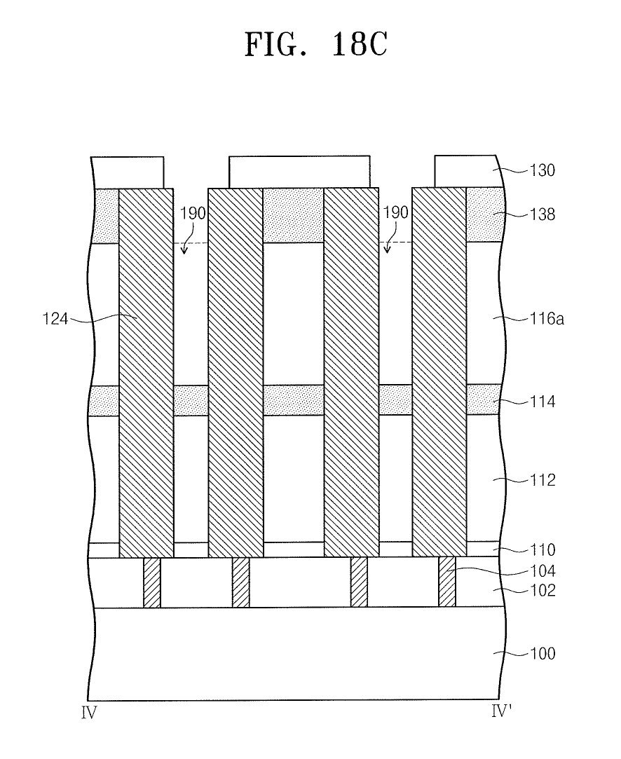

FIG. 18A illustrates a plan view depicting a stage of a method of fabricating a semiconductor device, according to some embodiments. FIGS. 18B and 18C illustrates cross-sectional views taken along a line IV-IV′ of FIG. 18A to depict stages of a method of fabricating a semiconductor device, according to some embodiments. Hereinafter, the same elements as described in the above embodiments will be indicated by the same reference numerals or the same reference designators. In addition, the descriptions to the same elements as in the above embodiments will not be repeated or will be mentioned only briefly for the purpose of ease and convenience in explanation.

Referring to FIGS. 18A and 18B, a second support pattern 138 may be formed by the processes described with reference to FIGS. 14A and 14B, and then a wet etching process may be performed to remove the second mold layer 116. The second mold layer 116 may be removed by an etching solution provided through the first openings 137 of the second support pattern 138. Thus, a top surface of the first support layer 114 may be exposed. The etching solution may have an etch selectivity with respect to the second support pattern 138 and the first support layer 114. For example, the etching solution may include a LAL solution.

In certain embodiments, as illustrated in FIGS. 18A and 18C, the second support pattern 138 may be formed by the processes described with reference to FIGS. 14A and 14B, and then the second mold layer 116 exposed by the first openings 137 may be etched by a dry etching process. Thus, a second mold pattern 116a having third openings 190 may be formed. A portion of the top surface of the first support layer 114 may be exposed through each of the third openings 190.

Thereafter, the processes described with reference to FIGS. 14A to 17A and 14B to 17B may be performed.

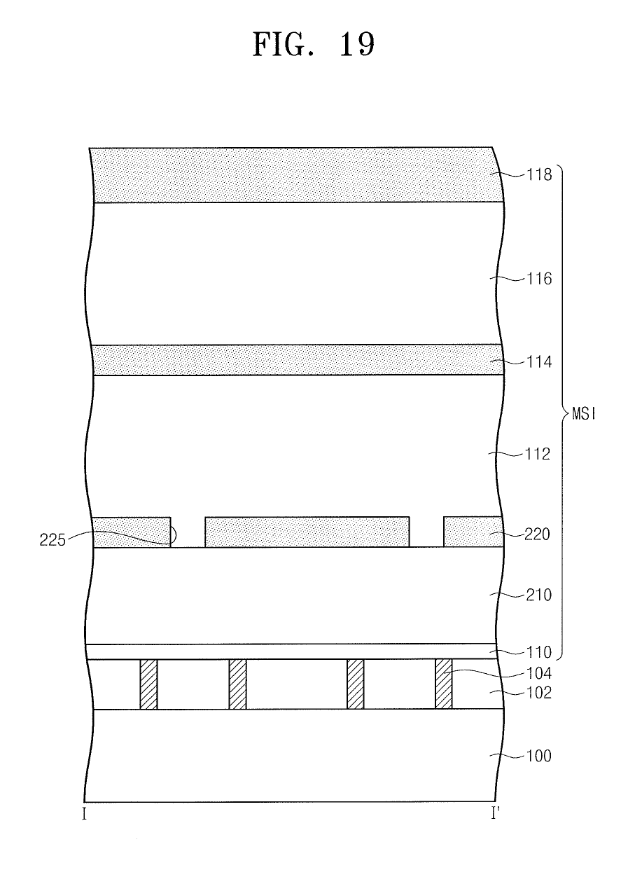

FIGS. 19 to 22 illustrate cross-sectional views depicting stages of a method of fabricating a semiconductor device, according to some embodiments. Hereinafter, the same elements as described in the above embodiments will be indicated by the same reference numerals or the same reference designators. In addition, the descriptions regarding the same elements as in the above embodiments will not be repeated or will be mentioned only briefly for the purpose of ease and convenience in explanation.

Referring to FIG. 19, an interlayer insulating layer 102 including contact plugs 104 may be formed on a substrate 10. A mold structure MS1 may be formed on the interlayer insulating layer 102. The mold structure MS may include an etch stop layer 110, a lowermost mold layer 210, a lowermost support pattern 220, a first mold layer 112, a first support layer 114, a second mold layer 116, and a second support layer 118 which are sequentially stacked on the interlayer insulating layer 102.

The lowermost mold layer 210 may be formed on the etch stop layer 110. The lowermost mold layer 210 may be formed of a material having an etch selectivity with respect to the etch stop layer 110, the lowermost support pattern 220, the first support layer 114, and the second support layer 118. For example, the lowermost mold layer 210 may include a silicon oxide (SiO₂) layer or an oxide layer including germanium (Ge).

The lowermost support pattern 220 may be formed on the lowermost mold layer 210. A lowermost support layer may be formed on the lowermost mold layer 210, and a patterning process may be performed on the lowermost support layer to form the lowermost support pattern 220. For example, the patterning process may include a photolithography process and an etching process. The lowermost support pattern 220 may have lowermost openings 225 by the patterning process. In some embodiments, the lowermost openings 225 may overlap with the first portions P1 of the second support layer 118 and the third portions P3 of the first support layer 114, which are illustrated in FIG. 4B, when viewed from a plan view.

The first mold layer 112 may be formed on the lowermost support pattern 220. The first mold layer 112 may cover a top surface of the lowermost support pattern 220. In addition, the first mold layer 112 may fill the lowermost openings 225 so as to be in contact with a top surface of the lowermost mold layer 210.

The first support layer 114, the second mold layer 116, and the second support layer 118 may be the same as described with reference to FIGS. 1A and 1B, and thus the descriptions thereto will not be repeated.

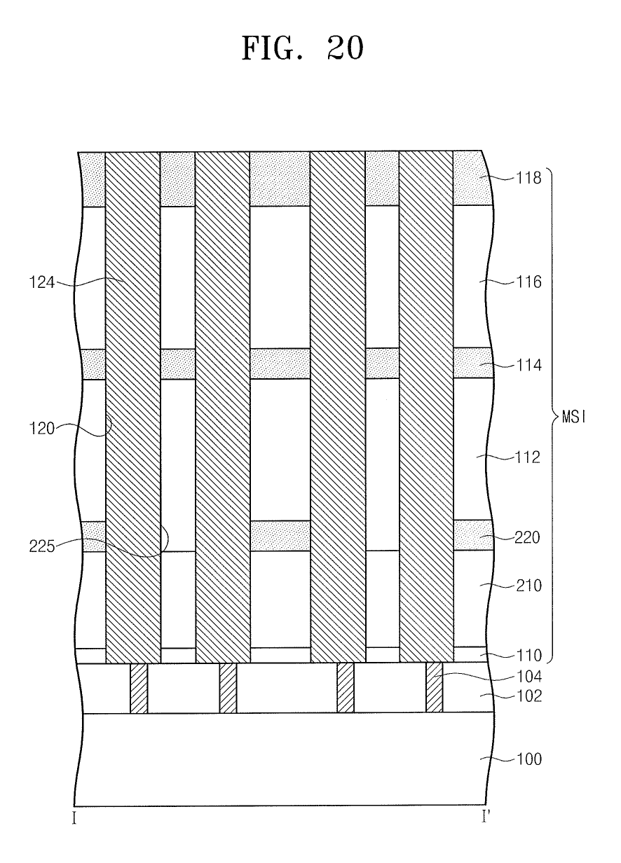

Referring to FIG. 20, lower electrodes 124 may be formed to penetrate the mold structure MS1. The second support layer 118, the second mold layer 116, the first support layer 114, the first mold layer 112, the lowermost support pattern 220, the lowermost mold layer 210, and the etch stop layer 110 may be sequentially patterned to form electrode holes 120, and the lower electrodes 124 may be formed in the electrode holes 120 by filling the electrode holes 120 with a metal material. A portion of the sidewall of each of the lower electrodes 124 may be in contact with the lowermost support pattern 220. After the formation of the lower electrodes 124, each of the lowermost openings 225 may be defined by adjacent lower electrodes 124 and the lowermost support pattern 220 connecting the adjacent lower electrodes 124.

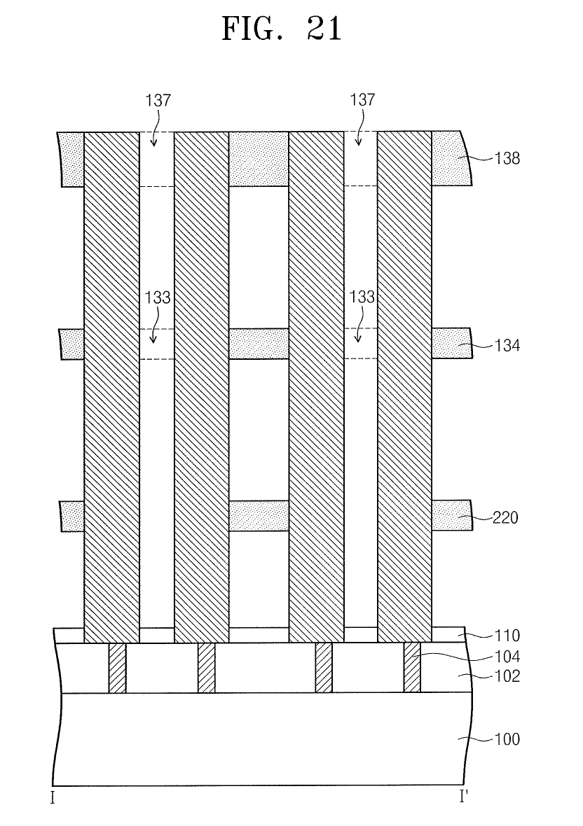

Referring to FIG. 21, the processes described in the above embodiments may be performed to form the second support pattern 138 and the first support pattern 134 and to remove the second mold layer 116, the first mold layer 112, and the lowermost mold layer 210. A top surface and a bottom surface of the lowermost support pattern 220 may be successively exposed by the removal of the first mold layer 112 and the lowermost mold layer 210.

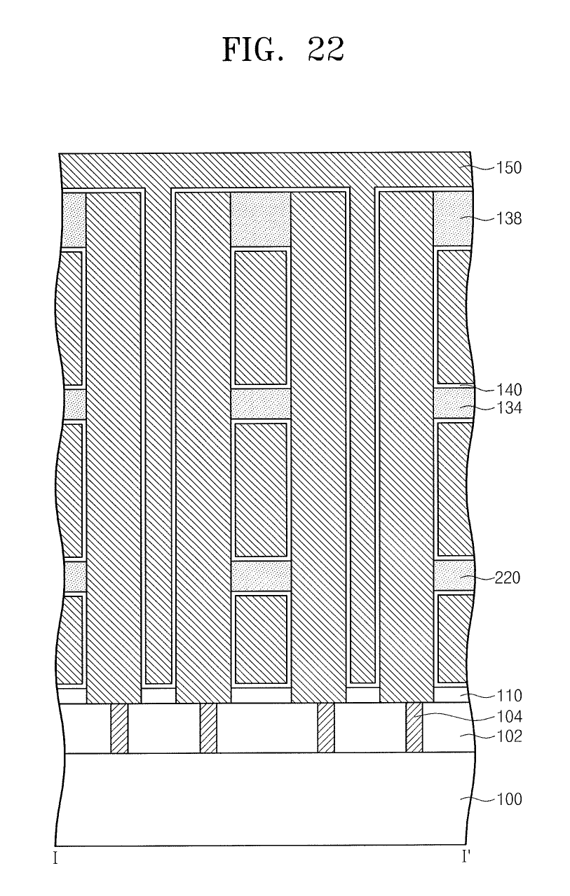

Referring to FIG. 22, a dielectric layer 140 and an upper electrode layer 150 may be sequentially formed on surfaces of the lower electrodes 124, the top and bottom surfaces of the first support pattern 134, the top and bottom surfaces of the second support pattern 138, the top and bottom surfaces of the lowermost support pattern 220, and the top surface of the etch stop layer 110.

According to some embodiments, first portions of a lower support layer, in which openings will be formed, may be doped with impurities. The first portions may have an etch selectivity with respect to a second portion of the lower support layer surrounding the first portions. Thus, the first portions may be selectively removed using an etching solution to form the openings. As a result, it is possible to easily form a lower support pattern having the openings.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. A method of fabricating a semiconductor device, the method comprising:
forming a mold structure including a lower support layer and an upper support layer that are sequentially stacked on a substrate;
doping portions of the upper and lower support layers with impurities to divide each of the upper and lower support layers into first portions doped with the impurities and a second portion surrounding the first portions in a plan view; and
removing the first portions of the upper and lower support layers to form an upper support pattern having first openings and a lower support pattern having second openings.

2. The method as claimed in claim 1, wherein the first portions are doped with the impurities by an ion implantation process.

3. The method as claimed in claim 1, wherein the impurities include at least one of boron (B), carbon (C), germanium (Ge), or fluorine (F).

4. The method as claimed in claim 1, wherein:
the first portions include at least one of SiBN, SiCN, SiGeN, or SiFN, and
the second portion includes silicon nitride.

5. The method as claimed in claim 1, wherein:
forming of mold structure includes sequentially stacking a lower mold layer, the lower support layer, an upper mold layer, and the upper support layer on the substrate, and
the lower and upper mold layers include a material having an etch selectivity with respect to the second portions of the upper and lower support layers.

6. The method as claimed in claim 1, further comprising:
forming lower electrodes before doping the portions of the upper and lower support layers, the lower electrodes penetrating the mold structure and being spaced apart from each other on the substrate.

7. The method as claimed in claim 6, wherein:
a portion of a sidewall of an upper portion of each of the lower electrodes is in contact with the upper support pattern, and
a portion of a sidewall of a lower portion of each of the lower electrodes is in contact with the lower support pattern.

8. A method of fabricating a semiconductor device, the method comprising:
forming a mold structure including a mold layer and a preliminary support layer that are sequentially stacked on a substrate;
forming lower electrodes penetrating the mold structure;
doping portions of the preliminary support layer with impurities to form a support layer including first portions doped with the impurities, the first portions being in contact with portions of the lower electrodes;
removing the first portions of the support layer to form a support pattern having openings exposing portions of the lower electrodes and the mold layer; and
removing the mold layer exposed through the openings to expose sidewalls of the lower electrodes.

9. The method as claimed in claim 8, wherein:
the mold structure further includes an upper mold layer and a preliminary upper support layer sequentially stacked on the preliminary support layer, and
the method further includes, after forming the lower electrodes, patterning the preliminary upper support layer to form an upper support pattern having upper openings exposing portions of the lower electrodes and portions of the upper mold layer.

10. The method as claimed in claim 9, wherein the openings overlap with the upper openings when viewed in a plan view.

11. The method as claimed in claim 9, wherein an upper portion of the upper support pattern is doped with the impurities during the formation of the support layer.

12. The method as claimed in claim 11, wherein the upper portion of the upper support pattern is removed when the first portions of the support layer are removed, such that a thickness of the upper support pattern is reduced.

13. The method as claimed in claim 11, wherein the upper portion of the upper support pattern includes a same material as the first portions of the support layer.

14. The method as claimed in claim 8, wherein:
the mold structure further includes an upper mold layer and a preliminary upper support layer sequentially stacked on the preliminary support layer,
doping the portions of the preliminary support layer with impurities to form the support layer further includes doping portions of the preliminary upper support layer with the impurities to form an upper support layer including second portions doped with the impurities, and
the second portions overlap with the first portions when viewed in a plan view.

15. The method as claimed in claim 14, further comprising, before forming the support pattern:
removing the second portions of the upper support layer using an etching solution to form an upper support pattern having upper openings exposing portions of the lower electrodes and portions of the upper mold layer.

16. A method of fabricating a semiconductor device, the method comprising:
forming a mold structure including at least a first mold layer, a lower support layer, a second mold layer and an upper support layer that are sequentially stacked on a substrate;
forming lower electrodes to extend through the upper support layer, second mold layer, lower support layer and first mold layer, each lower electrode contacting a contact plug in the substrate;
forming a mask pattern on the mold structure to define regions in the mold structure for forming upper electrodes;
doping the upper support layer and the lower support layer in the regions for forming upper electrodes with impurities such that each of the upper and lower support layers are divided into first portions doped with the impurities, the first portions being in the regions for forming the upper electrodes, and a second portion surrounding the first portions in a plan view, such that the first portions of the upper and lower support layers have an etching selectivity with respect to the second portions; and
removing the first portion of the upper support layer, the second mold layer, the first portion of the lower support layer and the first mold layer in the region for forming upper electrodes, wherein portions of the lower electrodes adjoining the region for forming upper electrodes are exposed, and wherein at least one of the first portion of the upper support layer, the second mold layer, the first portion of the lower support layer and the first mold layer in the region for forming upper electrodes is removed by wet etching using an etchant having an etch selectivity that preferentially removes the first portions relative to the second portions.

17. The method as claimed in claim 16, wherein:
the lower support layer and the upper support layer include silicon nitride, and
the impurities include at least one of boron (B), carbon (C), germanium (Ge), or fluorine (F), such that at least one of SiBN, SiCN, SiGeN, or SiFN is formed in the first portions of the lower support layer and the upper support layer.

18. The method as claimed in claim 16, further including forming a dielectric layer on the exposed portions of the lower electrodes and forming the upper electrodes on the dielectric layer.

19. The method as claimed in claim 16, wherein:
second portions of the lower support layer remaining after removing the doped lower support layer form a lower support pattern, a portion of a sidewall of a lower portion of each of the lower electrodes being in contact with the lower support pattern, and
removing the first mold layer exposes a bottom surface of the first support pattern.

20. The method as claimed in claim 19, wherein,
second portions of the upper support layer remaining after removing the doped upper support layer form an upper support pattern, a portion of a sidewall of an upper portion of each of the lower electrodes being in contact with the upper support pattern, and
removing the second mold layer exposes a bottom surface of the second support pattern and a top surface of the first support pattern.
